(19) United States
(12) Patent Application Publication
(10) Pub. No.: US 2026/0354028 A1
(43) Pub. Date: Nov. 5, 2026

(54) PIEZOELECTRIC ELEMENT, LIQUID DISCHARGE HEAD, COATING SOLUTION FOR PIEZOELECTRIC FILM, AND METHOD FOR MANUFACTURING PIEZOELECTRIC FILM

(71) Applicant: CANON KABUSHIKI KAISHA, Tokyo (JP)

(72) Inventors: MOTOKAZU KOBAYASHI, Kanagawa (JP); TAKAYUKI WATANABE, Kanagawa (JP)

(21) Appl. No.: 19/659,903

(22) Filed: Apr. 27, 2026

(30) Foreign Application Priority Data
Apr. 30, 2025 (JP) 2025-075395
Feb. 9, 2026 (JP) 2026-019041

(51) Int. Cl. H10N 30/00; B41J 2/14; B41J 2/16; H10N 30/079; H10N 30/081; H10N 30/853

(52) U.S. Cl. CPC H10N 30/708; B41J 2/14233; B41J 2/161; B41J 2/1645; H10N 30/079; H10N 30/081; H10N 30/8554; B41J 2202/03

(57) ABSTRACT

An inter-crystallization layer includes silica (SiO₂), and in a case where an atomic weight concentration of silicon (Si) in a cross section of the inter-crystallization layer in a direction parallel to a thickness direction of the inter-crystallization layer is measured by scanning from a surface side of the lower electrode to a surface side of the upper electrode of the inter-crystallization layer in the thickness direction by energy-dispersive fluorescent X-ray spectroscopy (EDX), a peak position of the number of counts of characteristic X-rays (K-lines) is located in a range of ½ of a thickness of the inter-crystallization layer on the surface side of the upper electrode, and wherein an amount of SiO₂ contained in the piezoelectric film is 0.1 wt % or more and 0.7 wt % or less.

### BACKGROUND

### Field of the Technology

The present disclosure relates to a piezoelectric element, a liquid discharge head, a coating solution for a piezoelectric film, and a method for manufacturing a piezoelectric film.

### Description of the Related Art

A piezoelectric film is a film having the property of changing its shape by applying a voltage to the film, and lead zirconium titanate (PZT) is well known. The piezoelectric film provided on a substrate is used for an inkjet printer, various actuators, a sensor, and the like through processing.

Examples of a manufacturing method for preparing such a piezoelectric film include a sputtering method, a metal-organic chemical vapor deposition method (an MOCVD method), a sol-gel method, and the like. Among these, the sol-gel method has difficulty forming a thick film at a time, but can form a film in a large area with excellent reproducibility by repeating a film formation process based on coating, heating, and sintering without requiring large-scale equipment. The sol-gel method is also a method useful in that the method can significantly decrease crystallization temperature.

The piezoelectric film requires a piezoelectric constant and a permittivity according to the use. When the piezoelectric film is used for a liquid discharge head of an inkjet printer or an actuator, the piezoelectric film requires a particularly high piezoelectric constant.

In terms of power consumption, the piezoelectric film requires a low permittivity. Japanese Patent Laid-Open No. 2015-192009 describes a technique for setting the ratios among lead (Pb), zirconium (Zr), titanium (Ti), manganese (Mn), and niobium (Nb) atoms in PZT doped with Mn and Nb within particular ranges, thereby obtaining a piezoelectric film having a high piezoelectric constant and a low permittivity.

However, in the adjustment of the metal atom ratios and the doping of manganese (Mn) and niobium (Nb) in the lead zirconium titanate (PZT) piezoelectric film described in Japanese Patent Laid-Open No. 2015-192009, a decrease in the relative permittivity is seen, but at the same time, a decrease in the piezoelectric constant is also seen. As described above, it is difficult to control each of the piezoelectric constant and the permittivity.

### SUMMARY

According to an aspect of the present disclosure, there is provided a piezoelectric element including a substrate, a lower electrode, a piezoelectric film, and an upper electrode, wherein the substrate, the lower electrode, the piezoelectric film, and the upper electrode are laminated together in this order, wherein the piezoelectric film contains at least lead (Pb), zirconium (Zr), and titanium (Ti) as constituent elements and includes an inter-crystallization layer, wherein the inter-crystallization layer includes silica (SiO₂), and in a case where an atomic weight concentration of silicon (Si) in a cross section of the inter-crystallization layer in a direction parallel to a thickness direction of the inter-crystallization layer is measured by scanning from a surface side of the lower electrode to a surface side of the upper electrode of the inter-crystallization layer in the thickness direction by energy-dispersive fluorescent X-ray spectroscopy (EDX), a peak position of the number of counts of characteristic X-rays (K-lines) is located in a range of ½ of a thickness of the inter-crystallization layer on the surface side of the upper electrode, and wherein an amount of SiO₂ contained in the piezoelectric film is 0.1 wt % or more and 0.7 wt % or less.

As another aspect, the present disclosure is directed to a coating solution for forming a piezoelectric film including lead zirconium titanate, the coating solution including a compound at least including metal elements such as lead (Pb), zirconium (Zr), and titanium (Ti), a solvent, and hollow silica particles.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic vertical cross-sectional view of a piezoelectric substrate.

FIG. 2 is a schematic perspective view illustrating a liquid discharge head according to an embodiment.

FIG. 3 is a schematic perspective cross-sectional view illustrating the liquid discharge head according to the embodiment.

FIG. 4 is a schematic cross-sectional view illustrating the liquid discharge head according to the embodiment.

FIG. 5 is a schematic cross-sectional view of hollow silica particles.

FIG. 6 illustrates a high-angle annular dark-field scanning transmission electron microscopy (HAADF-STEM) image of a part of a cross section of a piezoelectric film in example 1.

FIG. 7 is an energy-dispersive fluorescent X-ray spectroscopy (EDX) mapping image of characteristic X-rays of Si, obtained from the part of the cross section of the piezoelectric film in example 1 corresponding to FIG. 6.

FIG. 8 illustrates a silicon (Si) concentration profile by EDX measurement from a point A to a point C in FIG. 6.

FIG. 9 illustrates an HAADF-STEM image of a part of a cross section of a piezoelectric film in comparative example 2.

FIG. 10 is an Si concentration profile by EDX measurement from a point A to a point C in FIG. 9.

### DESCRIPTION OF THE EMBODIMENTS

The present inventors have given various considerations to a piezoelectric film and a method for manufacturing a piezoelectric film to achieve both a decrease in the permittivity and the maintenance of the piezoelectric constant in a piezoelectric film. As a result, the present inventors have found that if a piezoelectric film at least including lead (Pb), zirconium (Zr), and titanium (Ti) as constituent elements is manufactured using a coating solution containing hollow silica particles, it is possible to decrease the permittivity of the piezoelectric film while maintaining the piezoelectric constant of the piezoelectric film.

Some of the hollow silica particles are localized in an upper portion in an inter-crystallization layer of the piezoelectric film in a heating step or a sintering step among manufacturing steps. Specifically, a piezoelectric film prepared by a manufacturing method according to the present disclosure includes silica (SiO₂), and regarding the atomic weight concentration of silicon (Si) in an inter-crystallization layer of the piezoelectric film after being burnt, the concentration in ½ on one surface side of the inter-crystallization layer in the thickness direction of the inter-crystallization layer is lower than the concentration in ½ on the other surface side of the inter-crystallization layer. In other words, the piezoelectric film includes SiO₂, and regarding the atomic weight concentration of Si in the inter-crystallization layer of the piezoelectric film after being burnt, the concentration in ½ on the other surface side of the inter-crystallization layer in the thickness direction is higher than the concentration in ½ on the one surface side of the inter-crystallization layer. Further, in the piezoelectric film, the concentration in ⅓ on the other surface side of the inter-crystallization layer in the thickness direction is higher than the concentration in ⅓ on the one surface side of the inter-crystallization layer. In such a case, the atomic weight concentration of Si in a cross section is measured by scanning from the one surface side to the other surface side of the inter-crystallization layer in the thickness direction by energy-dispersive fluorescent X-ray spectroscopy. As a result, the peak of the number of counts of characteristic X-rays is located in the range of ½, more desirably in the range of ⅓, on the other surface side of the inter-crystallization layer.

In the present disclosure, one side of the piezoelectric film refers to the lower portion side of the piezoelectric film, and the other side of the piezoelectric film refers to the upper portion side of the piezoelectric film. That is, in a piezoelectric element in which a substrate, a lower electrode, the piezoelectric film, and an upper electrode are laminated together in this order, the one side refers to a surface on the lower electrode side, and the other side refers to a surface on the upper electrode side. In a case where the inter-crystallization layer is measured in the thickness direction by energy-dispersive fluorescent X-ray spectroscopy, the inter-crystallization layer may be measured from either the one side or the other side. In the present disclosure, the inter-crystallization layer is measured by scanning from the one side to the other side.

Although it is not known exactly why this concentration distribution occurs, it is guessed that this is because the specific gravity of the hollow silica particles is smaller than those of other components of the coating solution, and therefore, when the piezoelectric film melts in the sintering step, the hollow silica particles are localized in the upper portion in the layer, and a layer having a clearly low relative permittivity is formed. It is guessed that the formation of a layer having a low permittivity that does not affect the piezoelectric performance contributes to a decrease in the permittivity of the piezoelectric film.

The hollow silica particles in the piezoelectric film may be present in either the state where the hollow silica particles maintain a spherical shape or the state where the spherical shape is broken.

Embodiments of the present disclosure will be described in detail below. The present disclosure, however, is not limited to examples of the following embodiments.

### [Piezoelectric Substrate]

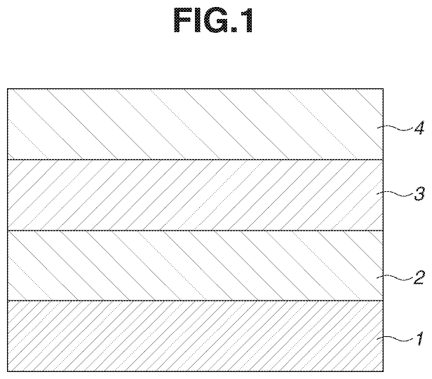

FIG. 1 is a schematic vertical cross-sectional view of a piezoelectric substrate according to an embodiment. FIG. 1 illustrates a substrate 1 that supports a piezoelectric film 3, a lower electrode (first electrode) 2, the piezoelectric film 3, and an upper electrode (second electrode) 4.

The material of the substrate 1 includes SiO₂ in the outermost layer. As a material other than SiO₂, a material that does not deform or melt even if a heat load is applied to the material in a heating step and a sintering step after coating is desirable. It is desirable that the surface of the substrate 1 be smooth, be able to prevent the diffusion of an element in heat treatment, and have sufficient mechanical strength. When a liquid discharge head is manufactured using a piezoelectric film obtained in the present embodiment, the substrate 1 may double as a pressure chamber substrate for forming a pressure chamber or a vibration plate of an actuator. For example, for such a purpose, a semiconductor substrate composed of silicon (Si) in which a surface layer is a film of SiO₂ due to thermal oxidation can be desirably used, but a ceramic of zirconia, alumina, silica, or the like may be used. If the outermost layer is SiO₂, a plurality of types of these materials may be combined together, or may be laminated together and used as a multilayer configuration.

The lower electrode 2 is formed of platinum (Pt) and can be formed with a thickness of 5 to 2000 nm. Although examples of a method for forming the lower electrode 2 include several methods such as a sol-gel method, a sputtering method, a vapor deposition method, and the like, the formation using the sputtering method is desirable because the electrode can be formed without increasing temperature. The thickness of the lower electrode 2 is not particularly limited so long as the thickness can obtain electrical conductivity. It is, however, desirable that the thickness of the lower electrode 2 be 10 nm or more and 1000 nm or less. The formed lower electrode 2 may be used by patterning the lower electrode 2 into a desired shape.

An intermediate layer that functions to bring the SiO₂ layer of the substrate 1 and the lower electrode 2 into close contact with each other may be provided between the SiO₂ layer of the substrate 1 and the lower electrode 2. As the material of the intermediate layer, Ti or Ti oxide is particularly desirable. It is desirable that the thickness of the intermediate layer be 2 nm or more and 30 nm or less.

The material of the piezoelectric film 3 is a piezoelectric body formed by the sol-gel method and at least including Pb, Zr, and Ti as constituent elements. Particularly, lead zirconium titanate having a perovskite structure represented by a general formula Pbₓ(Zr_{y}Ti_{1-y})O₃ (x=1.00 to 1.25, y=0.4 to 0.6, desirably y=0.5 to 0.55) includes an SiO₂ component derived from hollow silica particles. The composition of Zr and Ti is set in the above ranges, whereby it is possible to obtain a perovskite structure having high piezoelectricity.

A small amount of an element other than Pb, Zr, and Ti may be doped into the material of the piezoelectric film 3. Specific examples of the element that can be used as a dopant in a case where the doping is performed can include lanthanum (La), calcium (Ca), strontium (Sr), barium (Ba), tin (Sn), thorium (Th), yttrium (Y), samarium (Sm), cerium (Ce), bismuth (Bi), antimony (Sb), niobium (Nb), tantalum (Ta), tungsten (W), molybdenum (Mo), chromium (Cr), cobalt (Co), nickel (Ni), iron (Fe), copper (Cu), Si, germanium (Ge), scandium (Sc), magnesium (Mg), manganese (Mn), and the like. Particularly, it is desirable to use Nb as the metal dopant. A compound including these elements may be added when a coating solution is prepared. It is desirable that the additive amount of the metal dopant be 0.5 mol % or more and 5 mol % or less relative to Pbₓ(Zr_{y}Ti_{1-y})O₃.

As a method for manufacturing the piezoelectric film 3, the sputtering method, a metal-organic chemical vapor deposition (MOCVD) method, the sol-gel method, or the like is known. In the present disclosure, the sol-gel method and a method similar to the sol-gel method are used. In the sol-gel method, first, a substrate is coated with a coating solution containing a hydrolytic compound, a partially hydrolytic compound, or a partial polycondensation compound of component metals as a raw material (these compounds are collectively referred to as “precursors” in the present disclosure), and the coating solution is dried. Then, the coating solution is heated in the air and is crystallized by further sintering the coating solution at the crystallization temperature of the coating solution or more, thereby forming a piezoelectric thin film (a piezoelectric film). The sol-gel method can inexpensively and simply form a piezoelectric thin film.

Examples of the method similar to the sol-gel method include a metal-organic decomposition method (an MOD method). In the MOD method, a substrate is coated with a coating solution containing a thermally decomposable organic metal compound (a metal complex and a metal organic acid salt) such as a β-diketone complex or carboxylate of a metal as a precursor. Next, for example, a solvent in the coating solution is evaporated and the organic metal compound is thermally decomposed by heating the coating solution in the air or oxygen, and the coating solution is crystallized by further sintering the coating solution at the crystallization temperature of the coating solution or more, thereby forming a piezoelectric thin film.

In the present disclosure, the sol-gel method, the MOD method, and a method obtained by combining these methods are collectively referred to as the “sol-gel method”. A solution including a precursor manufactured by the “sol-gel method” is referred to as a “coating solution”. As the coating solution, a widely commercial coating solution may be used, or a coating solution manufactured from a raw material may be used as described below.

Examples of the commercial coating solution include “PZT-N” and “PZT-E” manufactured by Mitsubishi Materials Corporation, “PZT-10”, “PZT-20”, “PLZT-10”, and “PLZT-20” (all product names) manufactured by Kojundo Chemical Lab. Co., Ltd., and the like.

In the present embodiment, by a manufacturing method using a coating solution including hollow silica particles, the piezoelectric film 3 includes an Si component derived from the hollow silica particles inside. The piezoelectric film 3 is a piezoelectric film having a lower relative permittivity than that of a piezoelectric film manufactured from a coating solution not including hollow silica particles.

### [Liquid Discharge Head]

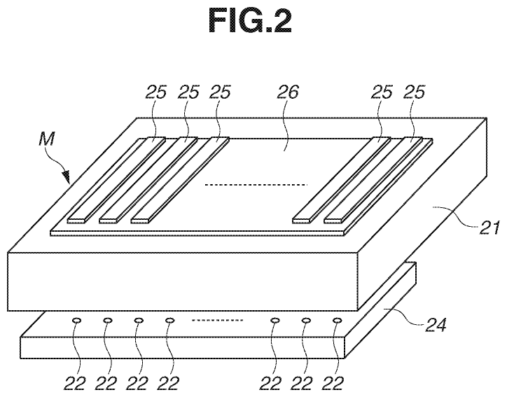

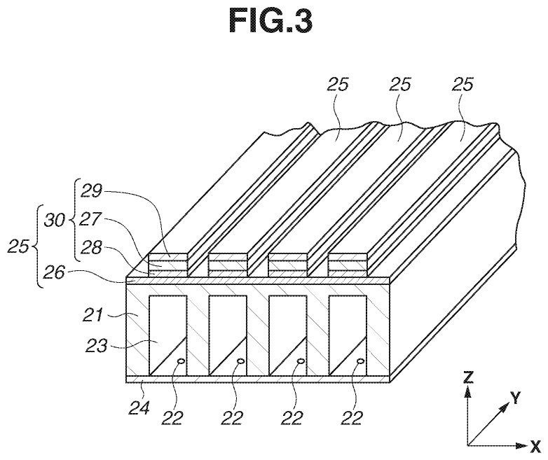

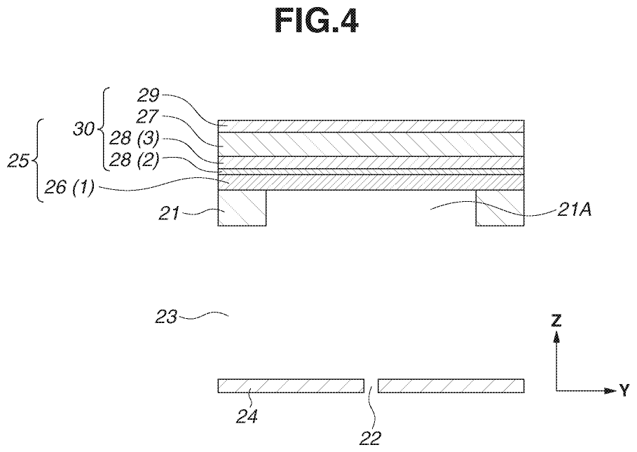

FIGS. 2 to 4 illustrate a liquid discharge head M according to the embodiment including the piezoelectric substrate. The liquid discharge head M includes discharge ports 22, pressure chambers 23 that communicate with the discharge ports 22, and actuators 25 that cause changes in the volumes of the pressure chambers 23 to discharge a liquid from the discharge ports 22. Then, the actuators 25 include a vibration plate 26 and piezoelectric elements 30 provided in order from the pressure chambers 23 side. Each piezoelectric element 30 includes a piezoelectric film 27 and a pair of electrodes (a lower electrode 28 and an upper electrode 29).

Each pressure chamber 23 is provided corresponding to one of the discharge ports 22 and communicates with the discharge port 22. Each piezoelectric element 30 provided on the vibration plate 26 is driven, thereby vibrating the actuator 25 and discharging a liquid in the pressure chamber 23 from the discharge port 22. The discharge ports 22 are formed at a predetermined interval on a nozzle plate 24, and the pressure chambers 23 are formed in parallel corresponding to the discharge ports 22 in a liquid discharge head substrate 21. In the present embodiment, each discharge port 22 is provided on the lower surface side of the actuator 25, but can be provided on the side surface side of the actuator 25. On the upper surface of the liquid discharge head substrate 21, opening portions (not illustrated) corresponding to the pressure chambers 23 are formed, and the actuators 25 are placed to cover the opening portions. The material of the vibration plate 26 is not particularly limited, but a semiconductor such as Si or the like, a metal, a metal oxide, glass, or the like is desirable. The piezoelectric elements 30 and the vibration plate 26 may be formed by joining or bonding, or the lower electrodes 28 and the piezoelectric elements 30 may be directly formed on a substrate using the vibration plate 26 as the substrate. Further, the vibration plate 26 may be directly formed on the liquid discharge head substrate 21.

Examples of the liquid discharged from the liquid discharge head M can include ink, various process liquids such as a reaction liquid that reacts with ink and the like, and the like.

### [Steps of Manufacturing Piezoelectric Film]

A method for manufacturing a piezoelectric film according to the present disclosure is described.

Steps of obtaining a piezoelectric film according to the present disclosure include a step of coating a substrate with a coating solution, a step of heating the coating solution on the substrate, and a step of sintering a dried film, thereby forming a piezoelectric film.

### (Method for Manufacturing Coating Solution)

As a method for manufacturing the coating solution, first, a liquid containing a hydrolytic compound or a partially hydrolytic compound of metal elements such as Pb, Zr, and Ti as a raw material is prepared. Examples of the raw material for generating this liquid can include an organic metal compound. Representative examples of the organic metal compound include an alkoxide, an organic acid salt, and a metal complex such as a β-diketone complex or the like of lead, titanium, and zirconium. As the metal complex, an amine complex or various other complexes can be used. Examples of the β-diketone for forming the β-diketone complex can include acetylacetone (=2,4-pentanedione), heptafluorobutanoylpivaloylmethane (=1-(heptafluoropropyl)-4,4-dimethyl-1,3-pentanedione), dipivaloylmethane (=2,2,6,6-tetramethyl-3,5-heptanedione), trifluoroacetylacetone, benzoylacetone, and the like.

As the coating solution, a coating solution containing a precursor compound of the piezoelectric film, such as a complex organic metal oxide of Pb, Ti, and Zr, is prepared by dissolving or dispersing each raw material organic metal compound into an appropriate organic solvent, performing heating treatment, and further hydrolyzing the resulting product. The complex organic metal oxide includes an organic substance containing Pb, an organic substance containing Ti, and an organic substance containing Zr. Particularly, it is desirable that the coating solution includes Nb.

The organic solvent used to prepare the coating solution is appropriately selected from various known solvents taking into account dispersiveness and coating properties. Examples of the organic solvent used to prepare the coating solution can include alcohol solvents such as methanol, ethanol, n-butanol, n-propanol, isopropanol, and the like, ether solvents such as tetrahydrofuran, 1,4-dioxane, and the like, cellosolve solvents such as methylcellosolve, ethylcellosolve, and the like, amide solvents such as N,N-dimethylformamide, N,N-dimethylacetamide, N-methylpyrrolidone, and the like, and nitrile solvents such as acetonitrile and the like. Among these, it is particularly desirable to use the alcohol solvents.

Although the amount of the organic solvent in the coating solution is not particularly limited, it is desirable to adjust the amount of the organic solvent so that the metal solid content concentration is 5 wt % or more and 30 wt % or less. If the metal solid content concentration is less than 5 wt %, the number of laminations to obtain a desired film thickness of the piezoelectric film increases, and it takes time to form the film. If the metal solid content concentration is greater than 30 wt %, the film thickness per layer is thick when the film is formed. Thus, cracks, peeling off, and the like are likely to occur.

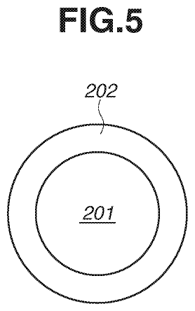

Further, the coating solution according to the present disclosure includes hollow silica particles, and the piezoelectric film after being formed includes an Si component derived from the hollow silica particles inside. The hollow silica particles refer to particles each including an outer shell formed of silica and having a cavity (a void) inside the outer shell. FIG. 5 is a schematic cross-sectional view of the hollow silica particles and illustrates an example where the shape of the hollow silica particles is substantially spherical. However, the hollow silica particles applicable to the present disclosure are not limited to this, and hollow silica particles having a different shape may be used. The hollow silica particles each include an outer shell 202 and a void 201 surrounded by the outer shell 202 and formed inside a hollow particle, and can be regarded as a type of core shell particles in which the core is air.

It is desirable that the diameter of the hollow silica particles be 30 nm or more and 100 nm or less, and the thickness of the outer shell 202 be about 2 nm or more and 20 nm or less. If the diameter is smaller than 30 nm, the volume occupied by the void 201 in the hollow silica particles is small, and therefore, a decrease in the relative permittivity of the piezoelectric film is small. If the diameter is greater than 100 nm, the crystal growth and the orientation of the piezoelectric film are likely to be inhibited.

The relative permittivity of the hollow silica particles is about 1.6, which is lower than the relative permittivity of solid-type silica particles, namely 3 to 4. Thus, a small amount of the hollow silica particles in a range that does not affect piezoelectricity is added, thereby exerting the effect of decreasing the relative permittivity of the piezoelectric film.

It is desirable to adjust the weight concentration of the hollow silica particles in the coating solution so that the amount of SiO₂ contained in the piezoelectric film after being formed is 0.1 wt % or more and 0.7 wt % or less. This is because if SiO₂ derived from the hollow silica particles in the piezoelectric film is 0.1 wt % or more, the effect of decreasing the relative permittivity is obtained more remarkably. If SiO₂ is 0.7 wt % or less, a decrease in the piezoelectric constant is less likely to occur.

As the hollow silica particles, a dispersion liquid of a commercial product may be used, or hollow silica particles manufactured from a raw material may be used. Examples of the dispersion liquid of the commercial hollow silica particles include “Thrulya” manufactured by JGC Catalysts and Chemicals Ltd. and the like.

### (Method for Forming Piezoelectric Film)

As a method for coating the substrate with the coating solution, any coating method such as spin coating, dip coating, bar coating, spray coating, or the like can be used. When the substrate is coated with the coating solution, it is desirable that the surface of the substrate with which the coating solution is coated be disposed in a horizontal direction (a direction orthogonal to a vertical direction). Consequently, it is possible to obtain a coated layer having a uniform film thickness. It is desirable to adjust the film thickness per layer in the coating so that the film thickness per layer after the sintering step is 100 nm or more and 300 nm or less. If the film thickness is less than 100 nm, it takes time to thickly form the piezoelectric film. If the film thickness is greater than 300 nm, cracks are likely to occur in the film.

In the heating step after the substrate is coated with the coating solution, the organic solvent is evaporated from the coated layer by heating. The temperature of the heating step may only need to be a heating temperature suitable for evaporating the organic solvent. It is desirable that the heating temperature be 50 °C or more and 400 °C or less. It is more desirable that the heating temperature be 100 °C or more and 350 °C or less. Although the heating time does not particularly matter so long as the organic solvent is evaporated, it is desirable that the heating time be in the range from approximately one minute to ten minutes.

In the heating step, it is desirable to heat the coating solution using a hot air heating machine, a hot plate, or the like. Heating steps using different warming methods may be used in combination, or different heating temperatures may be combined (e.g., after the coating solution may be dried at 100 °C, the coating solution may be dried again at 200 °C).

The sintering step after the heating step is performed for the purpose of removing the organic substances included in the film after being dried by sintering the film, promoting the crystallization of the coating solution, and forming the piezoelectric film. The sintering step can be performed by putting the substrate subjected to the heating step in a heat source such as a tubular furnace, an electric furnace, or the like, or bringing these heat sources into contact with the substrate. It is desirable that the temperature of the sintering step be 500 °C or more and 800 °C or less. The sintering step may be performed after each of the coating step and the heating step is performed once, or the sintering step may be performed after each of the coating step and the heating step is repeated multiple times. Either way may be employed. The series of steps including the coating step of coating the substrate with the coating solution, the heating step, and the sintering step is repeated multiple times until a desired thickness of the piezoelectric film is obtained. As described above, in the present disclosure, the piezoelectric film formed from the first coating step of coating a lower electrode to the first sintering step, or the piezoelectric film formed from the end of the sintering step to the end of the next sintering step is referred to as an “inter-crystallization layer”.

A seed layer for controlling the orientation of the piezoelectric film 3 may be provided between the piezoelectric film 3 and the lower electrode 2. The seed layer is a crystal layer having a function for placing the piezoelectric film 3 in a desired orientation such as a (100) surface orientation. The seed layer is formed by coating the substrate with a coating solution for the seed layer, heating the coating solution, and sintering the coating solution prior to the formation of the piezoelectric film 3. Although it is desirable that the coating solution for the seed layer have a composition similar to that of the piezoelectric film 3, a part of the composition may be changed. It is desirable that the thickness of the seed layer be 10 to 100 nm.

The thickness of the piezoelectric film 3 may be set according to the use. If the piezoelectric film 3 is used for an actuator, it is desirable that the thickness of the piezoelectric film 3 be 1 μm or more and 4 μm or less. If the piezoelectric film 3 is used for a sensor using pyroelectricity, the thickness of the piezoelectric film 3 may be less than 1 μm.

The material of the upper electrode 4 is not particularly limited, and can be appropriately selected from materials normally used for an electrode of a piezoelectric element. Examples of the material of the upper electrode 4 include metals such as Ti, Pt, Ta, iridium (Ir), Sr, indium (In), Sn, gold (Au), aluminum (Al), Fe, Cr, Ni, and the like and oxides of these. The composition of a single material among these materials may be used, or two or more of these materials may be used in combination. The upper electrode 4 may also be formed of the composition of a single material among the above materials, or a multilayer configuration may be obtained by laminating a plurality of these materials. The thickness of the upper electrode 4 is not particularly limited, but for example, can be 5 to 2000 nm.

### EXAMPLES

With reference to examples, the present disclosure is specifically described below. A relative permittivity and a piezoelectric constant (−d₃₁) were measured and an Si concentration profile in an inter-crystallization layer was obtained in each of the examples and comparative examples by the following methods.

### [Method for Measuring Relative Permittivity]

On the surface of a piezoelectric film prepared in each of examples 1 to 6 and comparative examples 1 to 4, Au having a diameter of 0.5 mm and a thickness of 100 nm was provided as an upper electrode by sputtering. An electrical capacitance was measured by applying an alternating current of 1 V and 1 kHz between the upper electrode and a lower electrode using an inductance, capacitance, and resistance (LCR) meter (LCR-6200 manufactured by Texio Technology Corporation), thereby obtaining the relative permittivity.

[Method for Measuring Piezoelectric Constant (−d₃₁)]

A substrate on which the piezoelectric film prepared in each of examples 1 to 6 and comparative examples 1 to 4 was formed was cut into a size of a width of 1.5 mm and a length of 12 mm. On the piezoelectric film of the cut substrate, Au was provided as an upper electrode from an end portion on the long side of the piezoelectric film to a position of 9 mm by sputtering. A position of 6 mm from an end portion on the side where the upper electrode was not provided was fixed with a clamp. The substrate was vibrated by applying an electric field (a frequency of 200 Hz, an offset 5 V, ±5 V, a sine wave) between the upper electrode and a lower electrode.

The amount of displacement of the end portion on the side where the upper electrode was not fixed with the clamp was measured using a laser Doppler apparatus (VibroOne VIO-130 manufactured by Polytec), thereby obtaining the piezoelectric constant (−d₃₁ [pm/V]).

### [Method for Obtaining Si Concentration Profile in Inter-Crystallization Layer]

A silicon substrate on which the piezoelectric film in example 1 was formed was processed into slices using a focused ion beam scanning electron microscope (FIB-SEM), and a cross section of the piezoelectric film sandwiched between a lower electrode and an upper electrode was observed using a scanning transmission electron microscope (STEM) (Talos F200E Super-X manufactured by Thermo Fisher Scientific Inc.; an acceleration voltage of 200 kV). An inter-crystallization layer (from an interface to an interface) could be confirmed using a high-angle annular dark-field scanning transmission electron microscopy (HAADF-STEM) image of a cross section in a direction parallel to the thickness direction of the inter-crystallization layer. In this portion of the inter-crystallization layer, a concentration profile of the Si element was created with respect to each nanometer in the film thickness direction by scanning transmission electron microscope energy-dispersive fluorescent X-ray spectroscopy (STEM-EDX).

### Example 1

As the coating solution for forming the seed layer, “PZT-E” (Pb/Zr/Ti=115/52/48) manufactured by Mitsubishi Materials Corporation was used. Regarding the coating solution for the piezoelectric film, “Thrulya 1110” (a grain diameter of 50 nm) manufactured by JGC Catalysts and Chemicals Ltd. was added as the hollow silica particles to “PZT-N” (Pb/Zr/Ti=110/52/48, a solid content of 17%) manufactured by Mitsubishi Materials Corporation so that the solid content of “Thrulya 1110” was 0.5 wt % relative to the solid content of 17% of “PZT-N”, and was agitated, thereby dispersing the hollow silica particles into the liquid. Then, the resulting product was used.

A film of Ti having a film thickness of 10 nm was formed on a silicon wafer (the outermost layer was SiO₂) of an 8-inch size, and further, a film of Pt having a film thickness of 100 nm was formed as a lower electrode by the sputtering method, thereby preparing a substrate in which the lower electrode was provided. This substrate was used by cutting the substrate into 4-cm squares.

First, the substrate was coated with the PZT-E liquid using a spin coater (2500 rpm, 100 seconds). Then, the PZT-E liquid was dried by placing the substrate for five minutes on a hot plate heated to 200 °C. Next, the PZT-E liquid was crystallized by sintering the PZT-E liquid at 700 °C for a minute under an oxygen atmosphere using an electric furnace, thereby forming a seed layer.

Further, the seed layer was coated with the coating solution for the piezoelectric film using the spin coater (2650 rpm, 100 seconds). Then, the coating solution was dried by placing the substrate for five minutes on the hot plate heated to 320 °C. After the coating of the seed layer with the coating solution and the heating of the coating solution on the hot plate were repeated twice, the coating solution was crystallized by sintering the coating solution at 800 °C for a minute under the oxygen atmosphere using the electric furnace. This series of operations was repeated eight times, thereby forming a piezoelectric film having a thickness of 2 μm in which the coating solution was laminated into a total of 16 layers (eight layers as inter-crystallization layers) on the substrate.

### Example 2

A film was formed similarly to example 1 except that the coating solution for the piezoelectric film in example 1 was changed so that the solid content of “Thrulya 1110” was 0.3 wt % relative to the solid content of 17% of “PZT-N”, thereby forming a piezoelectric film having a thickness of 2 μm on a substrate.

### Example 3

A film was formed similarly to example 1 except that the coating solution for the piezoelectric film in example 1 was changed so that the solid content of “Thrulya 1110” was 0.7 wt % relative to the solid content of 17% of “PZT-N”, thereby forming a piezoelectric film having a thickness of 2 μm on a substrate.

### Example 4

As the coating solution for forming the seed layer, an NbPZT-E liquid (Nb/Pb/Zr/Ti=2/120/52/48) manufactured by Mitsubishi Materials Corporation was used. Regarding the coating solution for the piezoelectric film, Thrulya 4110 (a grain diameter of 60 nm) manufactured by JGC Catalysts and Chemicals Ltd. was added as the hollow silica particles to an NbPZT-N liquid (Nb/Pb/Zr/Ti=2/115/52/48, a solid content of 17%) manufactured by Mitsubishi Materials Corporation so that the solid content of Thrulya 4110 was 0.5 wt % relative to the solid content of 17% of the NbPZT-N liquid, and was agitated, thereby dispersing the hollow silica particles into the NbPZT-N liquid. Then, the resulting product was used. A film of Ti having a film thickness of 10 nm was formed on a silicon wafer (the outermost layer was SiO₂) of an 8-inch size, and further, a film of Pt having a film thickness of 100 nm was formed as a lower electrode by the sputtering method, thereby preparing a substrate in which the lower electrode was provided. This substrate was used by cutting the substrate into 4-cm squares.

First, the substrate was coated with the NbPZT-E liquid using the spin coater (2500 rpm, 100 seconds). Then, the NbPZT-E liquid was dried by placing the substrate for five minutes on the hot plate heated to 200 °C. Next, the temperature was raised to 700 °C over 60 minutes under the oxygen atmosphere using the electric furnace, and then was returned to room temperature over three hours, thereby obtaining a seed layer.

Further, the substrate was coated with the NbPZT-N liquid prepared by adding the hollow silica particles, on the seed layer using the spin coater (2650 rpm, 100 seconds).

Then, the NbPZT-N liquid was dried by placing the substrate for five minutes on the hot plate heated to 320 °C. After the coating of the seed layer with the NbPZT-N liquid and the heating of the NbPZT-N liquid on the hot plate were repeated twice, the temperature was raised to 800 °C over 60 minutes under the oxygen atmosphere using the electric furnace, and then was returned to room temperature over three hours, thereby crystallizing the NbPZT-N liquid. These operations were repeated eight times, thereby laminating the NbPZT-N liquid to which the hollow silica particles were added into a total of 16 layers (eight layers as inter-crystallization layers), and forming a piezoelectric film having a thickness of 2 μm on the substrate.

### Example 5

The coating solution for the piezoelectric film in example 4 was added so that the solid content of Thrulya 4110 was 0.3 wt % relative to the solid content of 17% of the NbPZT-N liquid, and was agitated, thereby preparing a coating solution to which the hollow silica particles were added. A film was formed on a substrate similar to that in example 1 in steps similar to those in example 1, thereby forming a piezoelectric film having a thickness of 2 μm on the substrate.

### Example 6

The coating solution for the piezoelectric film in example 4 was added so that the solid content of Thrulya 4110 was 0.7 wt % relative to the solid content of 17% of the NbPZT-N liquid, and was agitated, thereby preparing a coating solution to which the hollow silica particles were added. A film was formed on a substrate similar to that in example 1 in steps similar to those in example 1, thereby forming a piezoelectric film having a thickness of 2 μm on the substrate.

### Comparative Example 1

A film was formed similarly to example 1 except that the coating solution for the piezoelectric film in example 1 was changed so that “PZT-N” (Pb/Zr/Ti=110/52/48, a solid content of 17%) was used as it was without adding “Thrulya 1110”, thereby forming a piezoelectric film having a thickness of 2 μm on a substrate.

### Comparative Example 2

The coating solution for the piezoelectric film in example 1 was changed from “Thrulya 1110” to a toluene-dispersed silica sol “TOL-ST” manufactured by Nissan Chemical Corporation, which was a dispersion liquid of solid silica particles. The coating solution for the piezoelectric film was prepared by adding “TOL-ST” so that the solid content of “TOL-ST” was 0.5 wt % relative to the solid content of “PZT-N”, and agitating “TOL-ST”. A film was formed similarly to example 1 except that the coating solution for the piezoelectric film was different, thereby forming a piezoelectric film having a thickness of 2 μm on a substrate.

### Comparative Example 3

A film was formed similarly to example 1 except that the coating solution for the piezoelectric film in example 1 was changed so that the solid content of “Thrulya 1110” was 1.0 wt % relative to the solid content of 17% of “PZT-N”, thereby forming a piezoelectric film having a thickness of 2 μm on a substrate.

### Comparative Example 4

The NbPZT-N liquid (Pb/Zr/Ti=115/52/48, a solid content of 17%) in example 4 was used as it was without adding Thrulya 4110. A film was formed on a substrate similar to that in example 4 in steps similar to those in example 4, thereby forming a piezoelectric film having a thickness of 2 μm on the substrate.

### [Evaluation Results]

Table 1 illustrates the relative permittivity and the piezoelectric constant (−d₃₁) of the piezoelectric film prepared in each of examples 1 to 6 and comparative examples 1 to 4.

TABLE 1

| | Contained Amount | | |
|---|---|---|---|
| | of Hollow Silica | Relative | Piezoelectric |
| | Particles | Permittivity | Constant −d₃₁ |
| | [wt %] | [—] | [pm/V] |
| Comparative | 0 | 2677 | 103 |
| Example 1 | | | |
| Comparative | 0 (0.5 wt % of | 2026 | 75 |
| Example 2 | solid silica | | |
| | particles) | | |
| Comparative | 1.0 | 1931 | 0 (no vibration) |
| Example 3 | | | |
| Comparative | 0 | 2570 | 104 |
| Example 4 | | | |
| Example 1 | 0.5 | 2050 | 103 |
| Example 2 | 0.3 | 2123 | 101 |
| Example 3 | 0.7 | 2033 | 82 |
| Example 4 | 0.5 | 1792 | 99 |
| Example 5 | 0.3 | 1908 | 102 |
| Example 6 | 0.7 | 1363 | 98 |

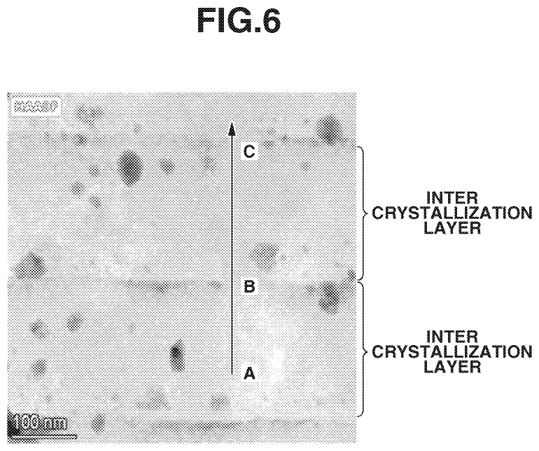

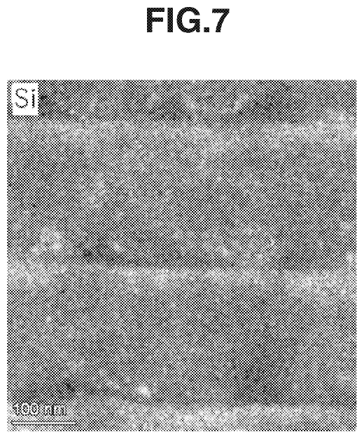

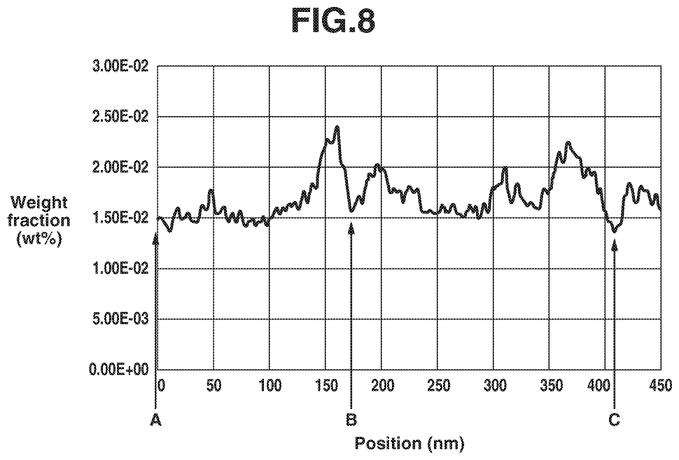

In each of examples 1 to 3, the piezoelectric constant (−d₁) comparable to that of the piezoelectric film not including the hollow silica particles in comparative example 1 was maintained, and in each of examples 1 to 3, the relative permittivity was smaller than that in comparative example 1. FIG. 6 illustrates an HAADF-STEM image of a part of a cross section of the piezoelectric film prepared in example 1. FIG. 7 illustrates an EDX element mapping image acquired in the range in FIG. 6. In FIG. 7, the lower the atomic weight concentration in the portion is, the blacker the mapped color of the portion is. The higher the atomic weight concentration in the portion is, the whiter the mapped color of the portion is. FIG. 8 illustrates an Si concentration profile from a point A to a point C extracted from the element mapping in FIG. 7. Each of a point B and the point C is a portion where an interface between inter-crystallization layers each formed by sintering can be confirmed. A portion between the points B and C is an inter-crystallization layer. In FIG. 8, the horizontal axis represents a position in the piezoelectric film (the point A is 0 nm), and the vertical axis represents a weight fraction (wt %) calculated from the number of counts of characteristic X-rays (K lines) of Si in the EDX measurement. From FIGS. 6 to 8, it is understood that the Si concentration in the inter-crystallization layer is high on the upper electrode side, and the peak position of the concentration profile is present on the upper electrode side. In other words, the peak position of the number of counts of characteristic X-rays (K-lines) of Si when the inter-crystallization layer is measured by scanning from one surface side to the other surface side of the inter-crystallization layer in the thickness direction of the inter-crystallization layer by EDX is located in the range of ½ on the other surface (upper electrode) side in the thickness of the inter-crystallization layer. When an inter-crystallization layer is measured in the thickness direction of the inter-crystallization layer by energy-dispersive fluorescent X-ray spectroscopy (EDX), the inter-crystallization layer is measured by scanning from one surface side (the lower electrode side) to the other surface side (the upper electrode side). In example 1, from FIG. 8, the peak position of the number of counts of characteristic X-rays (K-lines) of the Si concentration profile in the inter-crystallization layer was located in the range of ⅓ on the other surface side (the upper electrode side) in the thickness of the inter-crystallization layer. From the bias of the peak position, it is understood that in the inter-crystallization layer, the Si concentration in the range of ½ on the other surface (upper electrode) side was higher than the Si concentration in the range of ½ on the one surface (lower electrode) side. Also from the EDX element mapping image in FIG. 7, it can be seen that the Si concentration was high on the ½ side on the upper electrode side.

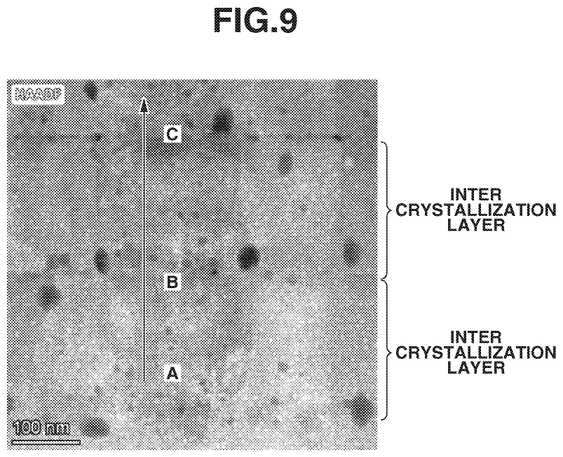

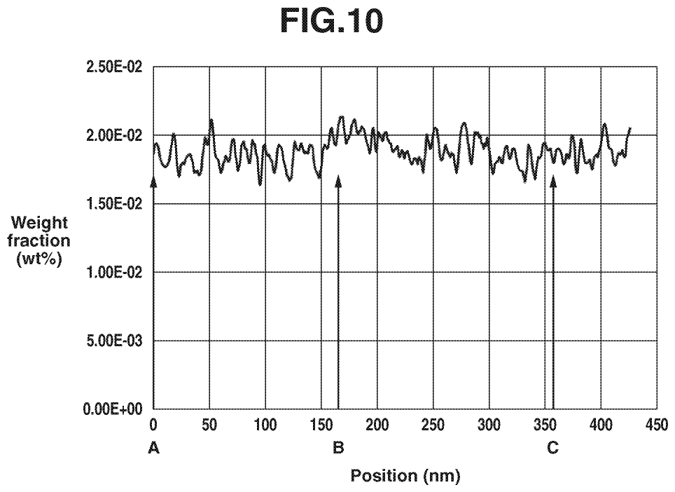

In comparative example 2 where the solid silica particles were used without using the hollow silica particles, the relative permittivity and the piezoelectric constant (−d₃₁) decreased compared to those in comparative example 1. FIG. 9 illustrates an HAADF-STEM image of a part of a cross section of the piezoelectric film prepared in comparative example 2. FIG. 10 illustrates an Si concentration profile from a point A to a point C extracted from an EDX element mapping image acquired in the range in FIG. 9. Each of a point B and the point C is a portion where an interface between inter-crystallization layers each formed by sintering can be confirmed. A portion between the points B and C is an inter-crystallization layer. In FIG. 10, the horizontal axis represents a position in the piezoelectric film (the point A is 0 nm), and the vertical axis represents a weight fraction (wt %) calculated from the number of counts of characteristic X-rays (K lines) of Si in the EDX measurement. From FIGS. 9 and 10, in comparative example 2 where not hollow silica but solid silica was added, a clear peak position of the Si concentration in the inter-crystallization layer was not observed.

In comparative example 3, the content rate of the hollow silica particles was 1.0 wt %, and the piezoelectric performance decreased due to the excess of the hollow silica particles. In comparative example 3, the piezoelectric constant (−d₃₁) was not able to be measured.

In examples 4 to 6 where Nb was added, the relative permittivity decreased compared to examples 1 to 3 where the same amount of the hollow silica particles was added, and a high piezoelectric constant was obtained.

In comparative example 4, Nb was added, but the hollow particles were not added. Thus, the relative permittivity was not able to be decreased.

According to the present disclosure, it is possible to provide a piezoelectric film having a low permittivity while maintaining a piezoelectric constant.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Applications No. 2025-075395, filed Apr. 30, 2025, and No. 2026-019041, filed Feb. 9, 2026, which are hereby incorporated by reference herein in their entirety.

What is claimed is:

1. A piezoelectric element comprising:
a substrate;
a lower electrode;
a piezoelectric film; and
an upper electrode,
wherein the substrate, the lower electrode, the piezoelectric film, and the upper electrode are laminated together in this order,
wherein the piezoelectric film contains at least lead (Pb), zirconium (Zr), and titanium (Ti) as constituent elements and includes an inter-crystallization layer,
wherein the inter-crystallization layer includes silica (SiO₂), and in a case where an atomic weight concentration of silicon (Si) in a cross section of the inter-crystallization layer in a direction parallel to a thickness direction of the inter-crystallization layer is measured by scanning from a surface side of the lower electrode to a surface side of the upper electrode of the inter-crystallization layer in the thickness direction by energy-dispersive fluorescent X-ray spectroscopy (EDX), a peak position of the number of counts of characteristic X-rays (K-lines) is located in a range of ½ of a thickness of the inter-crystallization layer on the surface side of the upper electrode, and
wherein an amount of SiO₂ contained in the piezoelectric film is 0.1 wt % or more and 0.7 wt % or less.

2. The piezoelectric element according to claim 1, wherein the thickness of the inter-crystallization layer is 100 nm or more and 300 nm or less.

3. The piezoelectric element according to claim 1, wherein the piezoelectric film is lead zirconium titanate represented by Pbₓ(Zr_{y}Ti_{1-y})O₃ (x=1.00 to 1.25, y=0.4 to 0.6).

4. The piezoelectric element according to claim 3, wherein the piezoelectric film includes 0.5 mol % or more and 5 mol % or less of a metal dopant relative to Pbₓ(Zr_{y}Ti_{1-y})O₃ (x=1.00 to 1.25, y=0.4 to 0.6).

5. The piezoelectric element according to claim 4, wherein the piezoelectric film contains Nb as the metal dopant.

6. The piezoelectric element according to claim 1, wherein in a case where the atomic weight concentration of Si in the cross section of the inter-crystallization layer in the direction parallel to the thickness direction of the inter-crystallization layer is measured by scanning from the surface side of the lower electrode to the surface side of the upper electrode of the inter-crystallization layer in the thickness direction by energy-dispersive fluorescent X-ray spectroscopy, the peak position of the number of counts of characteristic X-rays (K-lines) is located in a range of ⅓ of the thickness of the inter-crystallization layer on the surface side of the upper electrode.

7. The piezoelectric element according to claim 1, wherein regarding the atomic weight concentration of Si in the inter-crystallization layer, the concentration in ½ on the surface side of the upper electrode of the inter-crystallization layer in the thickness direction is higher than the concentration in ½ on the surface side of the lower electrode of the inter-crystallization layer.

8. The piezoelectric element according to claim 1, wherein the piezoelectric film includes a plurality of the inter-crystallization layers laminated together.

9. A piezoelectric element comprising:
a substrate;
a lower electrode;
a piezoelectric film; and
an upper electrode,
wherein the substrate, the lower electrode, the piezoelectric film, and the upper electrode are laminated together in this order,
wherein the piezoelectric film contains at least lead (Pb), zirconium (Zr), and titanium (Ti) as constituent elements and includes an inter-crystallization layer, and
wherein the inter-crystallization layer includes silica (SiO₂), and regarding an atomic weight concentration of silicon (Si) in the inter-crystallization layer, the concentration in ½ on a surface side of the upper electrode of the inter-crystallization layer in a thickness direction of the inter-crystallization layer is higher than the concentration in ½ on a surface side of the lower electrode of the inter-crystallization layer.

10. The piezoelectric element according to claim 1, wherein the piezoelectric film contains niobium (Nb).

11. A liquid discharge head comprising:
a piezoelectric element including:
a substrate;
a lower electrode;
a piezoelectric film; and
an upper electrode,
wherein the substrate, the lower electrode, the piezoelectric film, and the upper electrode are laminated together in this order,
wherein the piezoelectric film contains at least lead (Pb), zirconium (Zr), and titanium (Ti) as constituent elements and includes an inter-crystallization layer,
wherein the inter-crystallization layer includes silica (SiO₂), and in a case where an atomic weight concentration of silicon (Si) in a cross section of the inter-crystallization layer in a direction parallel to a thickness direction of the inter-crystallization layer is measured by scanning from a surface side of the lower electrode to a surface side of the upper electrode of the inter-crystallization layer in the thickness direction by energy-dispersive fluorescent X-ray spectroscopy (EDX), a peak position of the number of counts of characteristic X-rays (K-lines) is located in a range of ½ of a thickness of the inter-crystallization layer on the surface side of the upper electrode, and
wherein an amount of SiO₂ contained in the piezoelectric film is 0.1 wt % or more and 0.7 wt % or less, on a vibration plate,
wherein a liquid is discharged from a discharge port by driving the piezoelectric element.

12. A coating solution for forming a piezoelectric film including lead zirconium titanate, the coating solution comprising:
a compound including at least lead (Pb), zirconium (Zr), and titanium (Ti);
a solvent; and
hollow silica particles.

13. The coating solution according to claim 12, wherein a diameter of the hollow silica particles is 30 nm or more and 100 nm or less.

14. The coating solution according to claim 12, wherein the compound includes niobium (Nb).
